(19) United States
(12) Patent Application Publication
(10) Pub. No.: US 2024/0059180 A1
(43) Pub. Date: Feb. 22, 2024

(54) ELECTRIC VEHICLE STATE OF CHARGE CONTROL SYSTEM AND STATE OF CHARGE CONTROL METHOD THEREOF

(71) Applicants: Hyundi Motor Company, Seoul (KR); Kia Corporation, Seoul (KR)

(72) Inventor: Hye Joo Lee, Bucheon-si (KR)

(21) Appl. No.: 18/360,145

(22) Filed: Jul. 27, 2023

(30) Foreign Application Priority Data
Aug. 19, 2022 (KR) 10-2022-0104065

(51) Int. Cl. B60L 58/12; B60L 53/62

(52) U.S. Cl. CPC B60L 58/12; B60L 53/62; B60L 2250/16; B60L 2250/10; B60L 2240/545

(57) ABSTRACT

An embodiment state of charge (SOC) control method for an electric vehicle includes setting available power amount information based on power of a battery, receiving usage information on a usage device selected by a user from an external device and matching the usage information to preset load power data of a preset load power database, calculating predicted power amount information of the usage device based on the preset load power data and the available power amount information, and providing the predicted power amount to a user's device.

### CROSS-REFERENCE TO RELATED APPLICATIONS

The present application claims the benefit of Korean Patent Application No. 10-2022-0104065, filed on Aug. 19, 2022, which application is hereby incorporated herein by reference.

### TECHNICAL FIELD

The present disclosure relates to an electric vehicle state of charge control system and a state of charge control method thereof.

### BACKGROUND

Recently, as electric vehicles have become more popular, various functions using batteries or characteristics of electric vehicles are being developed or mass produced.

Various functions using the battery of the electric vehicle include a utility mode, a vehicle to load (V2L), a vehicle to grid (V2G)/vehicle-to-home (V2H), and the like.

The utility mode is a function of using the electric devices (multimedia, air conditioning, etc.) of an electric vehicle in a state in which the driving of the electric devices continues when the electric vehicle is stopped, in which the V2L is a function of using a high-voltage battery of the electric vehicle as a power supply source of an external power device, and the V2G/V2H is a function of exchanging power in conjunction with an external infrastructure.

In particular, in recent years, the power amount of an electric vehicle battery is increased due to a constant-speed battery, and the number of users who enjoy camping using an electric vehicle (that is, installing a tent around an electric vehicle or connecting an electric vehicle and a tent) or camping staying in an interior of an electric vehicle is increasing.

Meanwhile, electric vehicles display the discharging amount (kW) in real-time by introducing V2L technology, but there is a problem where it is difficult to estimate how much the real-time discharging amount can be used and how much the effect on the battery is when an external power device is actually consumed.

### SUMMARY

The present disclosure relates to an electric vehicle state of charge control system and a state of charge control method thereof. Particular embodiments relate to an electric vehicle state of charge control system and a state of charge control method thereof that can predict the time to reach a minimum charging amount by driving an external device with the power of a battery for driving an electric motor and calculating the power consumption of the external device that is driving or is scheduled to be driven.

Various embodiments of the present disclosure provide an electric vehicle SOC (state of charge) control system and an SOC control method thereof capable of increasing the usability of an external power device using a battery of an electric vehicle by effectively using the power for camping or the like by calculating a predicted value for power consumption in a V2L mode based on a general consumption amount and a real power consumption amount of the external power devices frequently used by users among electric devices (air conditioning/heater/multimedia) and a V2L (indoor/outdoor) device and predicting an estimated time to reach a minimum charging amount based on the predicted value.

Technical problems solvable by embodiments of the present disclosure are not limited to the above-mentioned technical problems, and other technical problems not mentioned will be clearly understood by those skilled in the art from the following description.

An SOC control method of an electric vehicle includes setting available power amount information based on power of a battery, receiving usage information on at least one usage device selected by a user from at least one external device and matching the usage information to preset load power data of a preset load power database (DB), calculating predicted power amount information of the at least one usage device based on the preset load power data and the available power amount information, and providing the predicted power amount to a user's device.

For example, wherein the setting of the available power amount information comprises extracting a characteristic value of power consumption according to a type of the electric vehicle, sensing a current external temperature of the electric vehicle, extracting a temperature weight value by matching the sensed current external temperature to a preset temperature factor, calculating a current SOC of the battery by applying at least one of the characteristic value of power consumption and the temperature weight value to the power of the battery, and calculating an available power amount value based on a minimum charging amount of the battery and the calculated current SOC of the battery.

For example, the available power amount information comprises at least one of the current SOC of the battery, the available power amount value, the characteristic value of power consumption, and the temperature weight value.

For example, the usage information includes basic information about the usage device and a predicted usage time of the usage device.

For example, the calculating of the predicted power amount information comprises analyzing the predicted power amount information based on the preset load power data and the available power amount information and predicting an estimated time at which the minimum charging amount can be reached based on a result of the analyzing.

For example, the predicting of the estimated time comprises predicting an estimated SOC for the battery together with the estimated time.

For example, the predicting of the estimated time further comprises transmitting a remaining time until the minimum charging amount to the user's device based on the estimated time and transmitting a notification to the user's device before the estimated time has been reached.

For example, the predicting of the estimated time comprises resetting the minimum charging amount before the estimated time is reached.

For example, the setting of the minimum charging amount comprises measuring and recording power data of a new device while the new device is being operated by the battery and transmitting the power data of the new device to the server.

A non-transitory computer-readable recording medium according to an embodiment of the present disclosure stores a program for executing the SOC control method as described above.

An electric vehicle SOC control system according to an embodiment of the present disclosure comprises a transitory computer-readable recording medium configured to store at least one computer program for performing an SOC control method and a processor configured to execute the at least one computer program, wherein the SOC control method includes setting available power amount information based on power of a battery, receiving usage information on at least one usage device selected by a user from at least one external device and matching the usage information to preset load power data of a preset load power DB, calculating predicted power amount information of the at least one usage device based on the preset load power data and the available power amount information, and providing the predicted power amount to a user's device.

For example, in the electric vehicle SOC control system, the setting of the available power amount information comprises extracting a characteristic value of power consumption according to a type of the electric vehicle, sensing a current external temperature of the electric vehicle, extracting a temperature weight value by matching the sensed current external temperature to a preset temperature factor, calculating a current SOC of the battery by applying at least one of the characteristic value of power consumption and the temperature weight value to the power of the battery, and calculating an available power amount value based on a minimum charging amount of the battery and the calculated current SOC of the battery.

For example, in the electric vehicle SOC control system, the available power amount information comprises at least one of the current SOC of the battery, the available power amount value, the characteristic value of power consumption, and the temperature weight value.

For example, in the electric vehicle SOC control system, the usage information includes basic information about the usage device and a predicted usage time of the usage device.

For example, in the electric vehicle SOC control system, the calculating of the predicted power amount information comprises analyzing the predicted power amount information based on the preset load power data and the available power amount information and predicting an estimated time at which the minimum charging amount can be reached based on a result of the analyzing.

For example, in the electric vehicle SOC control system, the predicting of the estimated time comprises predicting an estimated SOC for the battery together with the estimated time.

For example, in the electric vehicle SOC control system, the predicting of the estimated time further comprises transmitting a remaining time until the minimum charging amount to the user's device based on the estimated time and transmitting a notification to the user's device before the estimated time has been reached.

For example, in the electric vehicle SOC control system, the predicting of the estimated time comprises resetting the minimum charging amount before the estimated time is reached.

For example, in the electric vehicle SOC control system, the setting of the minimum charging amount comprises measuring and recording power data of a new device while the new device is being operated by the battery and transmitting the power data of the new device to the server.

The electric vehicle SOC control system and the SOC control method thereof according to at least one embodiment of the present disclosure configured as described above can accurately predict an estimated time to a minimum charging amount by calculating an expected value of V2L power consumption based on a general consumption amount, a real power consumption amount, and the like, of external power devices frequently used by users of the electric devices (air conditioning/heater/multimedia) and the V2L (indoor/outdoor) devices.

In addition, according to at least one embodiment of the present disclosure, the electric vehicle SOC control system and the SOC control method thereof can effectively use the power for camping or the like by using an accurately predicted minimum charging amount and an estimated time to increase usability of an external power device using a battery of the electric vehicle.

Also, the electric vehicle SOC control system and the SOC control method thereof according to at least one embodiment of the present disclosure can increase user convenience for V2L of the electric vehicle and can resolve existing concerns when using the battery of the electric vehicle.

The effects obtainable from embodiments of the present disclosure are not limited to the above-mentioned effects, and other effects not mentioned will be clearly understood from the following description by those skilled in the art to which the present disclosure pertains.

### BRIEF DESCRIPTION OF THE DRAWINGS

FIG. 1 is a block diagram illustrating an electric vehicle state of charge control system according to an embodiment of the present disclosure.

FIG. 2 is a block diagram illustrating an example of the configuration of an electric vehicle according to an embodiment of the present disclosure.

FIG. 3 is a block diagram illustrating an example of a head unit according to an embodiment of the present disclosure.

FIGS. 4A and 4B illustrate examples of a screen displayed on a display of a head unit according to an embodiment of the present disclosure.

FIG. 5 is a diagram illustrating a state of charge control method of an electric vehicle according to an embodiment of the present disclosure.

FIG. 6 is a diagram illustrating a method of adding a usage device according to an embodiment of the present disclosure.

FIGS. 7 to 9 are diagrams illustrating examples for adding new usage devices.

FIG. 10 is a diagram for describing an estimated time of arrival of a usage device according to an embodiment of the present disclosure.

The following reference identifiers may be used in connection with the accompanying drawings to describe embodiments of the present disclosure.
100: Electric vehicle
110: Controller
120: Battery
150: Sensing unit
200: Server
300: Smart device
310: Application
400: External device

### DETAILED DESCRIPTION OF ILLUSTRATIVE EMBODIMENTS

Hereinafter, embodiments of the present disclosure will be described in detail with reference to the accompanying drawings so that those skilled in the art to which the present disclosure pertains may easily implement the embodiments. However, the present disclosure may be implemented in various different forms and is not limited to the embodiments described herein. In order to clearly describe embodiments of the present disclosure in the drawings, parts not related to the description are omitted, and similar parts are denoted by similar reference numerals throughout the specification.

Throughout the specification, when a part “includes” a component, this means that other components may be further included without excluding other components unless specifically stated otherwise. In addition, parts indicated by the same reference numerals throughout the specification refer to the same components.

According to an embodiment of the present disclosure, it is proposed to calculate a predicted value for V2L consumption based on general consumption and the real power consumption of external power devices frequently used by users of electric devices (e.g., air conditioning/heater/multimedia) and V2L (indoor/outdoor) devices and to control to accurately predict an estimated time of arrival to a minimum charging amount based on the calculated predicted value.

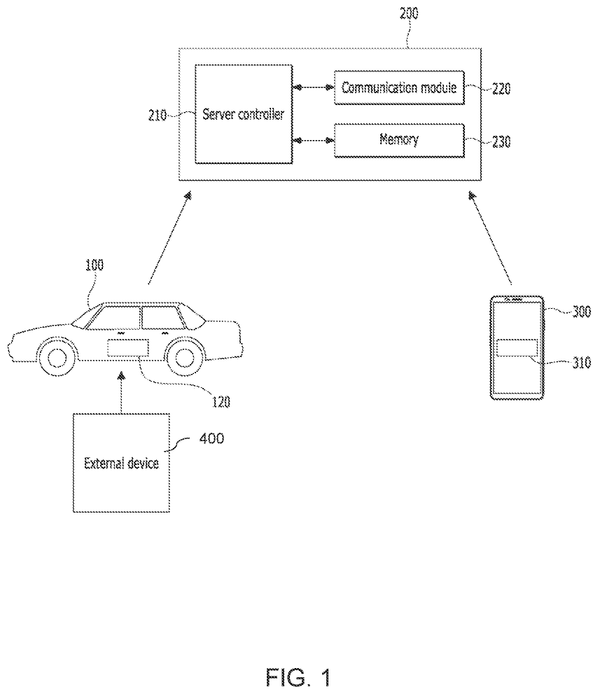

FIG. 1 is a block diagram illustrating an electric vehicle state of charge control system according to an embodiment of the present disclosure.

Referring to FIG. 1, the system for controlling a state of charge of an electric vehicle 100 may include the electric vehicle 100, a server 200, and a user device, e.g., a smart device 300.

The electric vehicle 100 may include a battery 120 for driving the electric motor.

When a minimum of one external device 400 is driven by power of the battery 120 in the V2L mode, the electric vehicle 100 may analyze the power of the battery 120 and transmit the available power amount information, which is the analyzed result value, to the server 200 using a wireless network or the like.

The battery 120 may be a high voltage battery 120. The power of the battery 120 may be a current state of charge (SOC) of the battery 120 when the mode is switched to the V2L mode from another mode such as a normal mode or a utility mode.

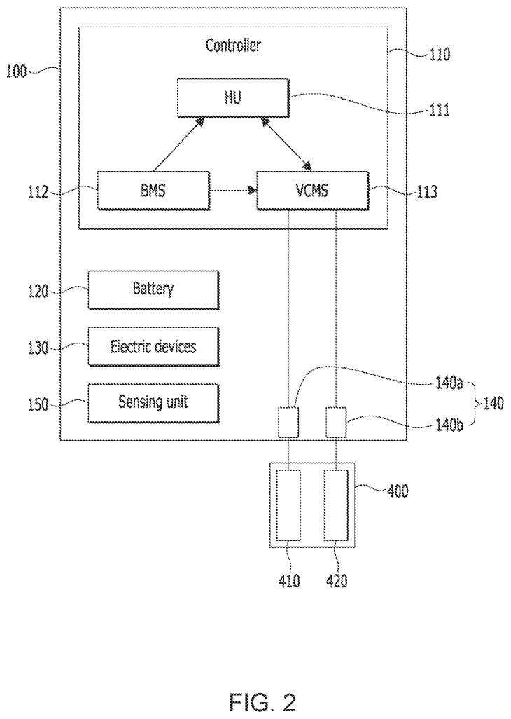

The external device 400 may be referred to as an external power device or an external electric device. Here, the external device 400 may be electrically connected to the high-voltage battery 120 through the indoor/outdoor connectors 140a and 140b (see FIG. 2) of the electric vehicle 100 and may include all power devices capable of using the high-voltage battery 120. For example, the external device 400 may include an electric pad, a mini lightbulb, a lantern, an induction, a mini oven, an electric pot, an electric grill, a mini refrigerator, a wine cellar, and the like.

When the electric vehicle 100 is determined to be in the V2L mode rather than in the normal mode, it may analyze a current SOC and extract available power amount information which may comprise a result value of the analysis based on the same. The available power amount information may be calculated based on an available power amount value up to the minimum charging amount from the current SOC. The available power amount value may be referred to as the amount of available power. Here, the minimum charging amount is defined as a minimum power amount needed to be retained and may be referred to as a minimum power amount, a minimum remaining power amount, or a minimum discharging amount.

The server 200 may collect available power amount information from the electric vehicle 100 through a wireless network or the like in the electric vehicle wo, compare and analyze the collected available power amount information with specification data to calculate power consumption data, and store the calculated power consumption data. The server 200 may be referred to as a connected car service (CCS) server 200 or an external server 200. The available power amount information may be referred to as power usage data. The specification data may be power consumption data displayed on the external device 400. That is, the specification data may be power consumption data indicated in the specification of the product. The load power database (DB) may store a plurality of specification data for various power devices and may update a plurality of power usage data in some cases.

The server 200 may include a server controller 210, a communication module 220, and a memory 230.

The server controller 210 may control various programs or devices necessary for the operation of the server 200. For example, the server controller 210 may control to match the usage information to a preset load power DB and calculate the predicted power amount information of the usage device based on the matched usage information and the available power amount information.

The server controller 210 may control to predict an expected state of charge of the battery 120 together with the estimated time of arrival. The server controller 210 may convert the calculated predicted power amount information of the used device into the SOC. In this case, the expected power amount to be consumed by the used device may be the value converted into the SOC.

As described above, the server 200 may calculate the expected power consumption per hour based on the power consumption DB of the general power device, which is the external device 400, under the control of the server controller 210. The power consumption DB may be referred to as a load power DB. In addition, the server 200 may control to add information or data on a power usage record (time/power amount/name of the power device/picture, etc.) used in its own electric vehicle 100 to the actual usage DB in customization under the control of the server controller 210. That is, the power usage DB or the load power DB may update data on a power usage record (time/power amount/name of the power device/picture, etc.) used by the user.

That is, the server controller 210 may calculate the predicted power consumption amount based on the power usage data and the specification (rated power consumption) data that are used at least once in the electric vehicle 100 and are actually measured.

In addition, the server controller 210 may analyze the expected power amount information of the used device based on the matched usage information and the available power amount information and may predict the estimated time of arrival at which the minimum charging amount may be reached based on the analyzed result value.

The server controller 210 may extract the remaining time for the minimum charging amount based on the estimated time of arrival. The server controller 210 may transmit the extracted remaining time to the smart device 300 through the communication module 220 and may transmit a notification signal to the smart device 300 before the estimated time of arrival.

The server controller 210 may control the minimum charging amount to be reset before the estimated time of arrival. A detailed description thereof will be described later.

The communication module 220 may be provided with the available power amount information from the electric vehicle 100 and may provide the available power amount information or the calculated expected power amount information to the smart device 300.

The communication module 220 may be referred to as a wireless communication module 220. The wireless communication module 220 may provide a wireless communication function using a wireless radio frequency. The wireless communication module 220 may include a network interface or a modem for connecting to a network (i.e., an Internet, a LAN, a WAN, a telecommunication network, a cellular network, a satellite network, a POTS, or a 5G network).

The memory 230 may store various programs and a plurality of data necessary for the operation of the server 200. The memory 230 may be implemented as a non-volatile memory 230, a volatile memory 230, a flash memory 230, a hard disk drive (HDD), a solid state drive (SSD), or the like. The memory 230 is accessed by the server controller 210, and reading/recording/modifying/deleting/updating of the data by the server controller 210 may be performed.

Also, the memory 230 may separately store power usage data including the real power consumption amount actually used in the electric vehicle 100 and specification data including the power usage amount displayed on the external device 400. For example, the memory 230 may classify power consumption data into a load power DB for storing power consumption data and a specification DB for storing specification data and may store the load power DB and the specification DB.

For example, the load power DB may record a power usage record (e.g., time, power amount, name of the power device, pictures, etc.) or store the use of power used in the electric vehicle 100 by the user. For example, the specification DB may store the power amount used by the external device 400, such as the 55 W of an electric pad, the 7 W of a mini lightbulb, the 5 W of a lantern, the 75 W of an induction, the 95 W of a mini oven, the 30 W of an electric pot, the 70 W of an electric grill, the 60 W of a mini refrigerator, the 30 W of a wine cellar, and the like.

The server controller 210 may control to replace the real power usage value of the external device with the real power usage value based on the actually used power usage recorded in or stored in the load power DB.

However, the load power DB is not limited thereto and may store a product specification information value of a new external device that has not been used under the control of the server controller 210. For example, the server controller 210 may control the communication module 220 to access a homepage or a server of a new external device and may receive a product specification information value of the new external device from the homepage or the server. Embodiments of the present disclosure are not limited thereto, and the server controller 210 may receive a product specification information value for a new external device in various ways.

The smart device 300 may provide or receive various information or data through the server 200 and the wireless network. For example, the smart device 300 may receive the available power amount information from the server 200 and may provide the use information on at least one used device selected by the user from among the at least one external device 400 to the server 200.

The smart device 300 may include a smart terminal, a smart phone, a portable terminal, a mobile phone, a portable device, and the like.

The smart device 300 may include at least one application 310. The minimum of one application 310 may include an application 310 related to the electric vehicle 100. The application 310 may receive and display various information on the electric vehicle 100 through the server 200 or may set commands or defaults for remote control of the electric vehicle 100.

For example, the smart device 300 may confirm the real time, current SOC of the electric vehicle 100 through the application 310 and may confirm the arrival time when the electric vehicle reaches the calculated minimum charging amount based on the current SOC. However, embodiments of the present disclosure are not limited thereto, and the smart device 300 may display power consumption/estimated time based on the usage information of the used device set by the user through the application 310. A detailed description thereof will be described later.

FIG. 2 is a block diagram illustrating an example of the configuration of the electric vehicle according to an embodiment of the present disclosure.

Referring to FIG. 2, the electric vehicle 100 according to an embodiment may include the battery 120, a sensing unit 150, and a controller 110.

The battery 120 may store electric energy required for driving the electric vehicle 100 and may supply the electric energy while driving. The battery 120 may be a high voltage battery 120.

The sensing unit 150 may include at least one temperature sensor. The minimum of one temperature sensor may be disposed outside the electric vehicle 100 to sense the outside temperature or the outside air temperature of the electric vehicle 100 in real time and provide the sensed outside temperature or the sensed outside air temperature to the controller 110.

The controller no may include a head unit (HU) 111, a battery management system (BMS) 112, and a vehicle charging management system (VCMS) 113. However, embodiments of the present disclosure are not limited thereto, and each element illustrated in FIG. 2 mainly shows elements related to the embodiments of the present disclosure, and in actual implementation, it is apparent to those skilled in the art that embodiments of the present disclosure may further include an electric motor, a controller (for example, a motor controller) for individually controlling the electric motor, and the like.

The battery management system 112 may be referred to as a battery controller, and the vehicle charging management system 113 may be referred to as a general charging controller.

The head unit 111 may control transmission of information about a use record of the external device 400 actually used in the electric vehicle 100 to the server 200.

The head unit 111 not only provides the real-time power usage display, the minimum charging amount setting, and the like, but also controls to request a notification e.g., 30 minutes before the estimated time of arrival of the minimum charging amount from the smart device 300.

The battery management system 112 may measure the power amount consumption of the electric devices 130 installed in the electric vehicle 100 and may provide information about the measured power amount consumption to the head unit 111. For example, the electric devices 130 may include multimedia, air conditioning, an indoor mood lamp in the electric vehicle 100, and the like.

The battery management system 112 may be electrically connected to the battery 120 and may provide information about the battery 120 of the electric vehicle 100 to the head unit 111. The information about the battery of the electric vehicle 100 may include a current charging amount of the battery 120, the state of battery capacity, a current battery SOC, and the like.

When the measured battery amount reaches the minimum charging amount, the battery management system 112 may provide or request a blocking signal for blocking transmission of power to the external device 400 to the vehicle charging management system 113. Here, the minimum charging amount is defined as a minimum power amount to be retained and may be referred to as a minimum power amount, a minimum discharging amount, or a minimum remaining amount.

In addition, the battery management system 112 may predict an expected time required to reach a minimum charging amount based on the real-time discharging amount (kW).

The vehicle charging management system 113 may be electrically connected to the external device 400 to measure the usage amount or the power consumption amount of the external device 400 and provide the measured power consumption amount to the head unit 111. That is, the vehicle charging management system 113 can control all charging-related functions in the electric vehicle wo and implement V2L together with an integrated charging control unit (ICCU).

In addition, the vehicle charging management system 113 may stop the V2L mode when a blocking signal is provided from the battery management system 112. That is, when the blocking signal is detected, the vehicle charging management system 113 may induce or control to switch the V2L mode to the normal mode. Embodiments of the present disclosure are not limited thereto, and in some cases, the V2L mode may forcibly be switched to the normal mode.

The external device 400 may include a first external device 410 connected to or separated from the first connector 140a of the electric vehicle wo and a second external device 420 electrically connected to or separated from the second connector 140b of the electric vehicle 100. The first connector 140a may be referred to as an indoor connector, and the second connector 140b may be referred to as an outdoor connector. The first external device 410 may be a power device having a small power amount consumption that may be used in the interior of the electric vehicle wo, and the second external device 420 may be a power device having a large power amount consumption that may be used in the exterior of the electric vehicle wo. However, embodiments of the present disclosure are not limited thereto.

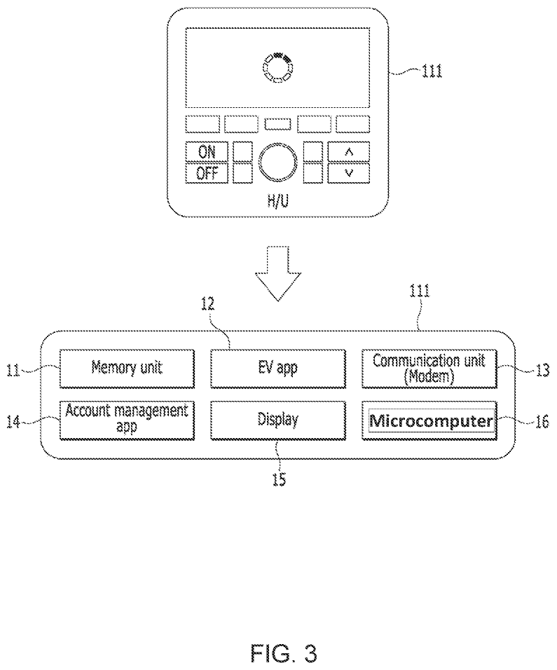

FIG. 3 is a block diagram illustrating an example of a head unit according to an embodiment of the present disclosure.

Referring to FIG. 3, the head unit 111 according to an embodiment of the present disclosure may include a memory unit 11, an electric vehicle (EV) app 12, a communication unit (e.g., modem) 13, an account management app 14, a display 15, and a microcomputer 16.

The memory unit 11 may record or store power consumption used in the electric vehicle 100. The memory unit 11 may store a use start/end time, a power amount, a connection type (indoor/outdoor/electric device), and the like, of all power devices used in the electric vehicle 100.

The EV app 12 may set a minimum charging amount of the battery 120. For example, the EV app 12 may set the V2L function to be ceased when the minimum charging amount is reached.

The communication unit 13 may transmit V2L usage information (power usage record) to the server 200. In the V2L mode, the communication unit 13 may provide, to the server 200, the power amount consumption information transmitted to the external device 400 and the available power amount set based on the power of the battery 120. That is, the communication unit 13 may provide the server 200 with information on the vehicle battery 120 and information on the expected time to reach the minimum charging amount based on the real-time discharging amount.

The account management app 14 may upload the account of the user and the terminal information on the smart device 300 together to manage the account so that the account is linked in the server 200 or the app. For example, the account of the user may include XXX@Hyundai.com, etc.

The account management app 14 may control to manage the power amount consumption of at least one external device 400 registered by the user. That is, the account management app 14 may control to internally manage a current usage value. The current usage value may be the power amount consumption of the at least one external device 400 registered by the user.

The account management app 14 may be linked with an app (or a phone app) installed in the server 200 or the smart device 300 to manage the real usage value by user customization. The real usage value of the user may be a real power consumption amount that is actually measured for a prescribed time in the external device 400 that has been used by being connected to the indoor/outdoor connector of the electric vehicle 100.

The display 15 may display the EV app 12 and the account management app 14 on a screen and may display various information related to the electric vehicle 100.

The microcomputer 16 may transmit/receive a real CAN signal to/from the BMS 112/VCMS 113 of the electric vehicle 100. The microcomputer 16 may transmit a user change value and the like, may receive various real-time data on the electric vehicle 100, and may transmit the various data to the EV app 12. For example, the user change value may be a value obtained by resetting the minimum charging amount.

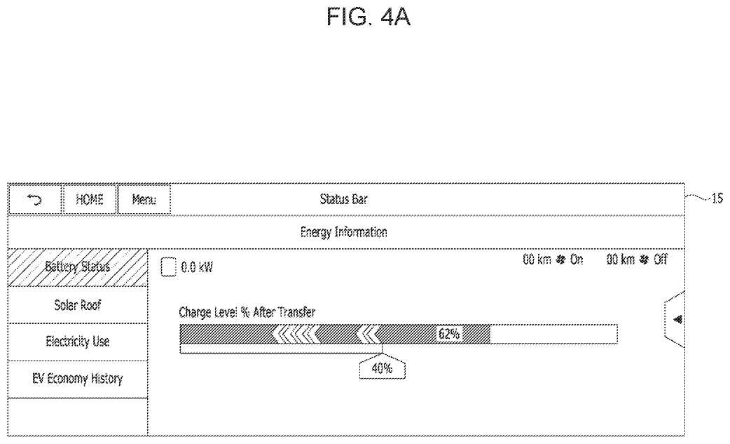

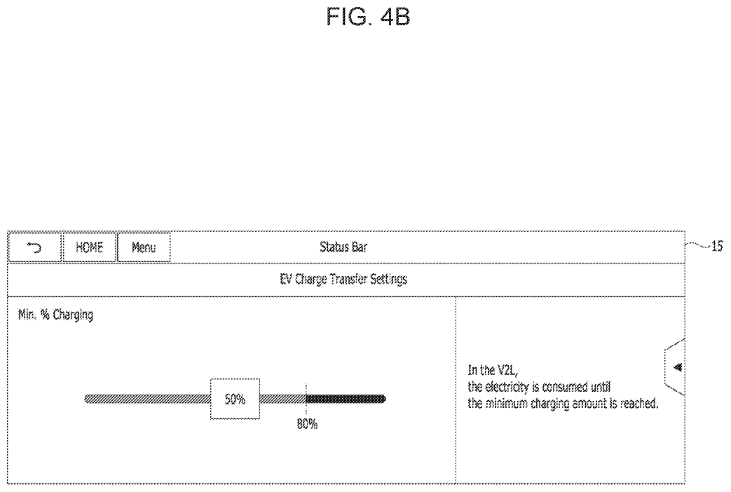

FIGS. 4A and 4B illustrate examples of a screen displayed on a display of a head unit according to an embodiment of the present disclosure.

Referring to FIG. 4A, the display 15 of the head unit 111 may display energy information about the electric vehicle 100. The display 15 of the head unit 111 may display a battery status of the electric vehicle 100 in a single shape of a bar. For example, the display 15 of the head unit 111 may display a case of switching from the normal mode to the V2L mode in the form of a bar.

Referring to FIG. 4B, when the mode is switched to the V2L mode, the display 15 of the head unit 111 may display a setting for the current SOC and the minimum charging amount in a fixed shape or may display a message related thereto. For example, the fixed shape may be a shape of a bar or a graph. For example, as illustrated in FIG. 4B, the display 15 of the head unit 111 may include a first screen and a second screen. The first screen may display that the current SOC is set to 80% and the minimum charging amount is set to 50% through a shape of a bar. A description of the current SOC and the minimum amount of charge according to the current state of mode may be displayed on the second screen. For example, the second screen may display messages such as “In the V2L, the electricity is consumed until the minimum charging amount is reached” or “XX % is left to reach the minimum charging amount, and Y˜YY minutes remain with the current power consumption rate.”

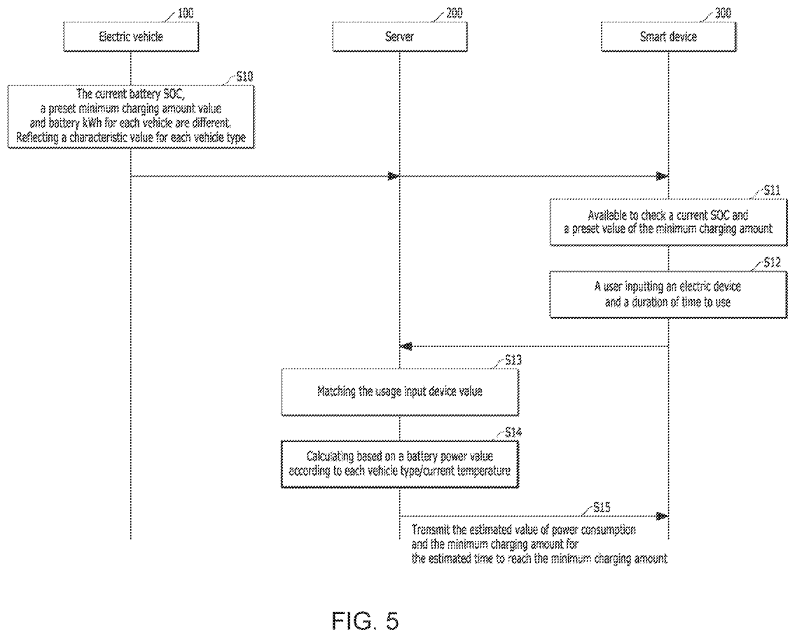

FIG. 5 is a diagram illustrating a state of charge control method of an electric vehicle according to an embodiment of the present disclosure.

Referring to FIG. 5, a state of charge control method of an electric vehicle according to an embodiment of the present disclosure is as follows.

In a V2L mode in which at least one external device is driven by power of a battery for driving an electric motor under control of a controller of an electric vehicle, embodiments of the present disclosure may set available power amount information based on the power of the battery.

That is, embodiments of the present disclosure, when in the V2L mode, may set the current SOC of the battery, the set minimum charging amount, the minimum charging amount value, the minimum charging amount information, and the like under the control of the controller of the electric vehicle.

Embodiments of the present disclosure may extract different power consumption characteristic values for each vehicle type of the electric vehicle 100 under the control of the controller of the electric vehicle 100 and may set a minimum charging amount value based on the extracted characteristic values of power consumption (S10). For example, when the vehicle type is the long-ranged IONIQ 5, the power characteristic value of consumption of the battery may be 76 kWh, when the vehicle type is the standard ranged IONIQ 5, the characteristic value of power consumption of the battery may be 64 kWh, when the vehicle type is the Kona EV, the characteristic value of power consumption of the battery may be 48 kWh, when the vehicle type is the Niro EV, the characteristic value of power consumption of the battery may be 48 kWh, when the vehicle type is the IONIQ EV, the characteristic value of power consumption of the battery may be 32 kWh, and when the vehicle type is the Soul EV, the characteristic value of power consumption of the battery may be 32 kWh. The above-described characteristic value of consumption for each type of vehicle is only one example and is not limited thereto.

Embodiments of the present disclosure can extract a temperature factor by sensing the current external temperature with respect to the surrounding environment of the electric vehicle under the control of a controller of the electric vehicle and matching the sensed current external temperature with a preset temperature range. The temperature factor may be referred to as a temperature weight value.

A SOC of a battery may minutely change an optimal performance of the battery in response to an external peripheral temperature. Accordingly, in reference to embodiments of the present disclosure, the temperature factors may be extracted as different values corresponding to the preset temperature range under the control of the controller of the electric vehicle 100. For example, the temperature factor may be extracted as 1.7 when the current external temperature sensed from the outside of the electric vehicle 100 is between minus (−) 10 and minus (−) 5 degrees, the temperature factor may be extracted as 1.5 when the current external temperature is between minus (−) 5 and 0 degrees, the temperature factor may be extracted as 1.2 when the current external temperature is between 0 and plus (+) 10 degrees, the temperature factor may be extracted as 1.0 when the current external temperature is between plus (+) 10 and plus (+) 20 degrees, the temperature factor may be extracted as 1.1 when the current external temperature is between plus (+) 20 and plus (+) 30 degrees, the temperature factor may be extracted as 1.2 when the current external temperature is between plus (+) 30 and plus (+) 35 degrees, and the temperature factor may be extracted as 1.3 when the current external temperature is between plus (+) 35 and plus (+) 40 degrees. The above-described preset temperature ranges and temperature factors are only one example and are not limited thereto.

That is, according to embodiments of the present disclosure, different temperature factors are extracted for each preset temperature range according to the currently sensed external temperature under the control of the controller of the electric vehicle 100, and the extracted temperature factors are applied, thereby making it possible to calculate the current SOC of the battery capable of exhibiting the optimal performance of the battery.

As described above, according to embodiments of the present disclosure, a SOC of the battery capable of exhibiting the optimal performance of the battery may be calculated by applying at least one of the characteristic value of power consumption and the temperature factor to the power of the battery under the control of the controller of the electric vehicle 100, and the available power amount value up to the minimum charging amount of the electric vehicle may be accurately calculated or extracted based on the calculated SOC of the battery.

The available power amount information may include at least one of a SOC of the battery, an available power amount value, a characteristic value of power consumption, and a temperature weight value.

In embodiments of the present disclosure, the server 200 may be provided with the information on the amount of available power from the electric vehicle 100 under the control of the server controller, and may provide the provided available power amount information to the smart device 300.

The smart device 300 may display the available power amount information through the application of the electric vehicle 100. That is, the user may check setting values of the current SOC and the minimum charging amount through the smart device 300 (S11).

The smart device 300 may set usage information of at least one used device selected by the user from at least one external device. The smart device 300 may set at least one device to be used by the selection of the user (S12).

The usage information may include basic information on the used device and an expected usage time of the used device. For example, the smart device 300 may select an electric pad for camping, a mini lightbulb, a mobile phone charger, and an electric pot, which are devices to be used through the app, and may set the predicted time of use of the device to be used as 1 PM to 6 PM. Further, the smart device 300 may confirm that the current SOC is 82% and the minimum charging amount is set to 20% by using the app.

The server 200 according to an exemplary embodiment of the present disclosure may receive the usage information from the smart device 300 under the control of the server controller and match the usage information with a preset load power DB (S13). The preset load power DB may store at least one external device and average power per time of the external device. The load power DB may be referred to as a power DB of a power device.

For example, the load power DB may store an electric pad for camping (average power of 14 W per hour), a mini lightbulb (average power of 7 W per hour), a lantern (average power of 75 W per hour), a portable induction (average power of 95 W per hour), a mini oven (average power of 30 W per hour), an electric pot (average power of 70 W per hour), a mini refrigerator (average power of 60 W per hour), and the like.

The server 200 of embodiments of the present disclosure may calculate the expected power amount information of the used device based on the matched usage information and the information on the amount of available power under the control of the server controller (S14). That is, the server 200 may analyze the predicted power amount information of the used device based on the matched usage information and the available power amount information under the control of the server controller and may predict the estimated time of arrival at which the minimum charging amount may be reached based on the analyzed result value.

The server 200 according to an exemplary embodiment of the present disclosure may predict an expected state of charge of the battery together with the estimated time of arrival under the control of the server controller.

The server 200 of embodiments of the present disclosure may provide the calculation of the predicted power amount information to the smart device 300 under the control of the server controller (S15).

The smart device 300 may display the predicted power amount information through the app. For example, the smart device 300 may display the content that the predicted power consumption is 4.3 kW, the predicted battery SOC is 54%, and the minimum charging amount may be reached when the used device is used for 17 hours and 20 minutes or more while using the app. Accordingly, embodiments of the present disclosure may accurately provide the user with predicted battery consumption information suitable for general electric device features to be used as V2L.

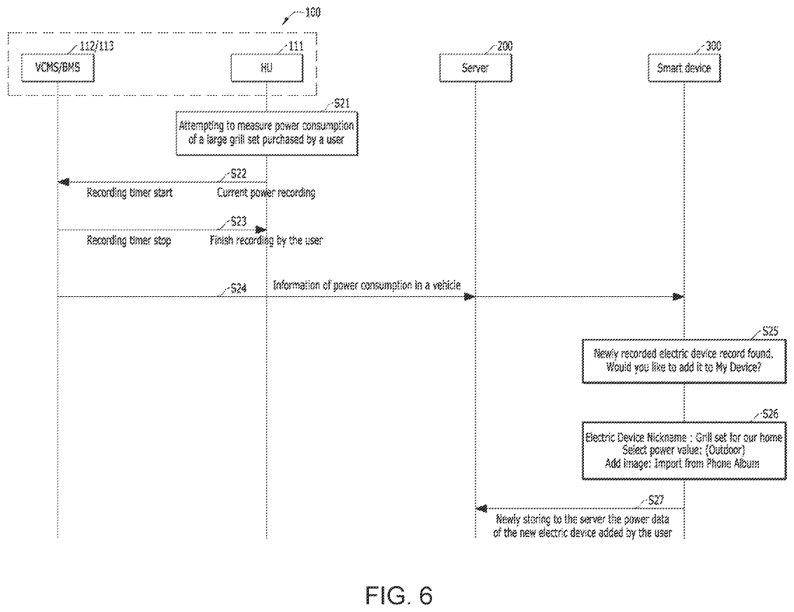

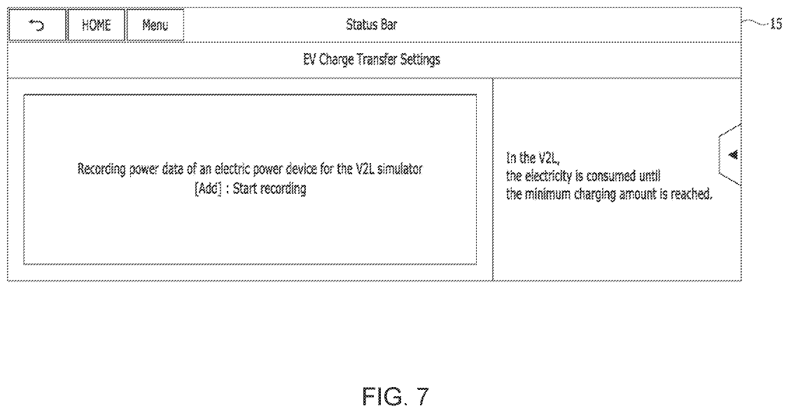

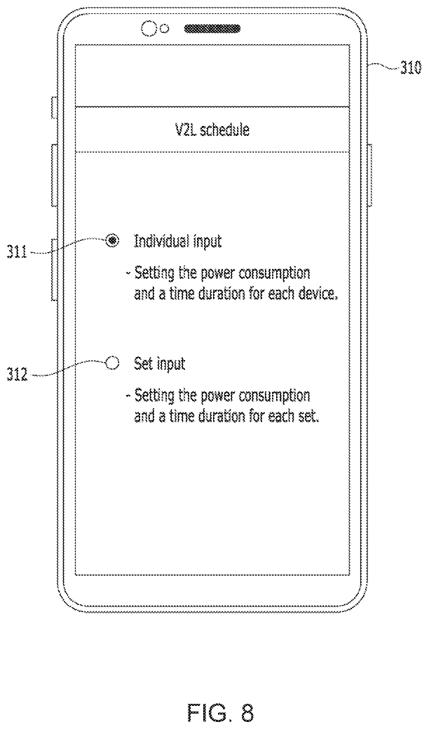

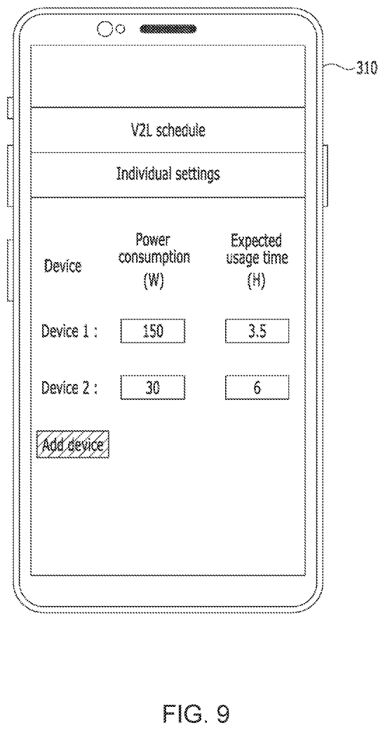

FIG. 6 is a diagram illustrating a method of adding a usage device according to an embodiment of the present disclosure. FIGS. 7 to 9 are diagrams illustrating examples for adding new usage devices.

Referring to FIG. 6, the controller of the electric vehicle 100 may control the electric vehicle to actually operate a new device for a prescribed time to measure and record the real power consumption of the new device.

The electric vehicle 100 may receive input of a new device from the user through the head unit 111. For example, the head unit 111 may measure power for a large grill set purchased by the user (S21). Here, the head unit 111 may include at least one touch screen, touch pad, key button, and dial, but this is merely an example, and any form is not limited as long as it is provided in an electric vehicle to receive information from a user. For example, the head unit 111 may include a speech recognition device. Also, the head unit 111 may include a display, a speaker, and the like, which outputs a guide information guide, a menu, or a user interface including both (see FIG. 3) in a fixed form to assist the user input information.

As shown in FIGS. 6 and 7, when a new device is connected and operated to the indoor/outdoor connector of the electric vehicle, the head unit 111 turns on the timer in response to the operation of the new device and receives information on the power amount consumed while the new device operates from the VCMS/BMS 112/113 and records the information (S22). The head unit 111 may display this through the display 15.

If a new user device does not operate after a prescribed time, the head unit 111 may turn off the timer and end the recording of the new user device (S23).

The head unit 111 may acquire, from the VCMS/BMS 112/113, real power consumption per hour consumed while the new device is substantially operated, based on the power consumption of the new device and data for a prescribed time measured from the timer.

In operation S24, the head unit 111 may provide the information about the power consumption of the new device to the server 200 by using the communication unit (not shown). The power amount information of the new device may include power consumption information in the vehicle and may also include real power, minimum power per hour, maximum power per hour, average power per hour, and the like.

In addition, the head unit 1111 may provide power consumption of the electric vehicle 100 using a communication unit (not shown). For example, the power consumption of the electric vehicle 100 may include an average power per hour of the electric device of the electric vehicle 100, an average power per hour of the user equipment that is electrically connected to the indoor connector and the outdoor connector and is consumed, and the like. For example, the average power per hour of the electric device may be 8 W, the average power per hour of the device used while being connected to the indoor connector may be 12 W, and the average power per hour of the device used while being connected to the outdoor connector may be 127 W.

The server 200 may store the information about the power amount of the new device and the power amount consumption of the electric vehicle 100 in the preset load power DB under the control of the server controller.

In addition, the server 200 may provide the smart device 300 with power amount information of the new user device by using the communication module (S24).

When the power amount information of the new user device is provided from the server 200, the smart device 300 may determine whether to store the power amount information of the new usage device using the app or not. For example, when it is determined that there is a record of a power device newly recorded in the electric vehicle through the power amount information of a new device using the app, the smart device 300 may add the new device as its own device in operation S25.

Referring to FIGS. 6, 8, and 9, the smart device 300 may perform an individual input 311 or a set input 312 by using the app 310 to provide new, detailed information on a new device used in its own electric vehicle 100. For example, when there is at least one new user device, power consumption and time of each of the new devices to be used may be set individually. For example, the new usage device may include the usage device 1 and the usage device 2. When the user individually clicks the input, the user may input 150 W of power consumption of the first device, input 3.5 hours of predicted usage time, input 30 W of power consumption of the second device, and input 6 hours of predicted usage time. When you click the “Add Device” button, you can continue adding devices.

Also, a minimum of one new device may be set, and power consumption and time may be set for each set. That is, in the case of the set input, the power consumption and the predicted usage time may be input by grouping the entire use of the full set rather than the specific usage device.

For example, the smart device 300 may input a nickname of a new usage device (or a power device) as a “Grill set for our home” through an app, and may input data regarding the power amount, an image of a new usage device, and the like (S26). For example, the new information may include a specific value related to power consumption, but is not limited thereto. Thereafter, the smart device 300 may transmit new information on the input new user device to the server 200.

The server 200 may receive new information about a new user device from the smart device 300 and update the new information in a preset load power DB as shown in Table 1. However, embodiments of the present disclosure are not limited thereto, and the server 200 may store a new usage device in a customized DB or the like in addition to the load power DB (S27).

TABLE 1

| | Average | | | |
|---|---|---|---|---|
| | power | | | |
| User device | per | Added | | |
| (Nickname) | hour | date | Section | Image |
| Grill set for | | | Outdoor | |
| our home | | | | |
| Loud woofer | | | Indoor/electric device | |
| Full camping | | | Indoor/outdoor/electric | |
| set | | | device | |

As described above, embodiments of the present disclosure may accurately predict power consumption based on a real usage value rather than a general power value.

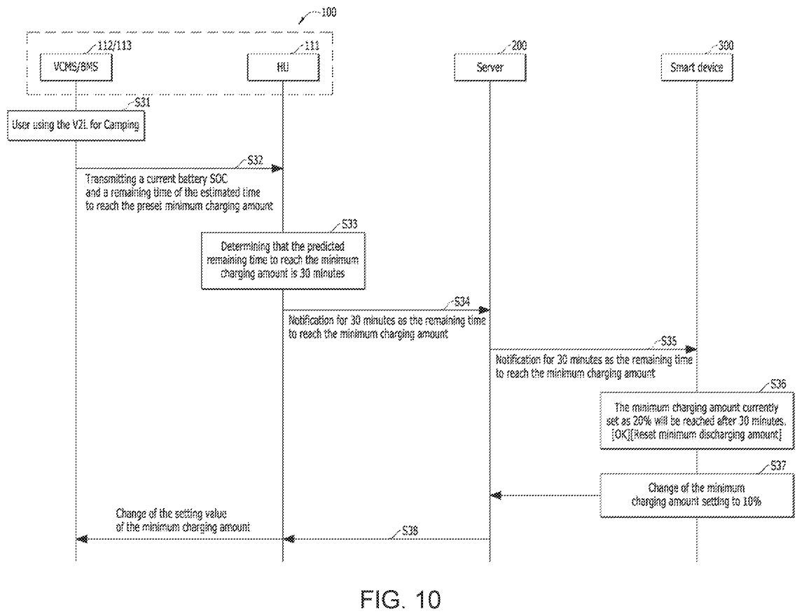

FIG. 10 is a diagram for explaining an estimated time of arrival of a minimum charging amount for a usage device according to an embodiment of the present disclosure.

Referring to FIG. 10, in a V2L mode where at least one external device is driven by power of a battery for driving an electric motor under the control of a controller of the electric vehicle 100 (S31), a SOC of the battery may be calculated by applying at least one of the characteristic value of power consumption and a temperature factor to the power of the battery.

According to embodiments of the present disclosure, it is possible to analyze the predicted power amount information of the user device based on the matched usage information and the available power amount information under the control of the controller of the electric vehicle 100 and predict the predicted time of arrival at which the minimum charging amount may be reached based on the analyzed result value (S32).

According to embodiments of the present disclosure, the remaining time for the minimum charging amount may be calculated based on the predicted time of arrival under the control of the controller of the electric vehicle 100 (S33), and information on the calculated remaining time may be transmitted to the server 200 (S34) and to the smart device 300 via the server 200 (S35). For example, the information about the calculated remaining time may be a predicted remaining reaching time of 30 minutes.

According to embodiments of the present disclosure, the notification signal may be transmitted to the smart device 300 before the predicted time of arrival is reached under the control of the controller of the electric vehicle 100.

When the notification signal is transmitted, the smart device 300 may maintain or reset the minimum charging amount through the app. When the minimum charging amount is maintained, the smart device 300 may transmit the maintenance signal to the electric vehicle 100 via the server 200.

When the maintenance signal is transmitted under the control of the controller, the electric vehicle 100 may block some of the usage devices. That is, the electric vehicle 100 may sequentially shut off the usage devices in the predetermined blocking order under the control of the controller. For example, the preset blocking order may be set based on power consumption of the usage device, may be set based on user settings, may be set based on the number of times of use of the user device, or may be set based on the difference for each time zone.

Contrarily, when the minimum charging amount is reset, the smart device 300 may reset the minimum charging amount while using the app. For example, a minimum charging amount set to 20% may be reset to 10%.

The smart device 300 may transmit information about the reset minimum charging amount to the server 200 (S37) and to the electric vehicle 100 via the server 200 (S38).

The electric vehicle 100 may change a setting value of a minimum charging amount based on the reset minimum charging amount.

The controller no, the head unit in, the BMS 112, and the VCMS 113 each may comprise one or more processors (e.g., computer, microprocessor, CPU, ASIC, circuitry, logic circuits, etc.) which perform the functionalities described above by executing one or more computer programs stored in one or more non-transitory computer-readable mediums. Also, the processors of the head unit in, the BMS 112, and the VCMS 113 may be separately provided or integrated in one processor.

Embodiments of the present disclosure described above may be implemented as computer-readable codes in a medium in which a program is encoded. The computer-readable medium includes all types of recording devices in which data readable by a computer system are stored. Examples of the computer-readable medium include a hard disk drive (HDD), a solid state disk (SSD), a silicon disk drive (SDD), a ROM, a RAM, a CD-ROM, a magnetic tape, a floppy disk, an optical data storage device, and the like.

Accordingly, the above detailed description should not be construed as being limited in all aspects and should be considered as illustrative. The scope of the present disclosure should be determined by rational interpretation of the appended claims, and all changes within the equivalent scope of the present disclosure are included in the scope of the present disclosure.

What is claimed is:

1. A state of charge (SOC) control method for an electric vehicle, the method comprising:
setting available power amount information based on power of a battery;
receiving usage information on a usage device selected by a user from an external device and matching the usage information to preset load power data of a preset load power database;
calculating predicted power amount information of the usage device based on the preset load power data and the available power amount information; and
providing the predicted power amount to a user's device.

2. The method of claim 1, wherein setting the available power amount information comprises:
extracting a characteristic value of power consumption according to a type of the electric vehicle;
sensing a current external temperature of the electric vehicle;
extracting a temperature weight value by matching the sensed current external temperature to a preset temperature factor;
calculating a current SOC of the battery by applying the characteristic value of power consumption or the temperature weight value to the power of the battery; and
calculating an available power amount value based on a minimum charging amount of the battery and the calculated current SOC of the battery.

3. The method of claim 2, wherein the available power amount information comprises the current SOC of the battery, the available power amount value, the characteristic value of power consumption, or the temperature weight value.

4. The method of claim 2, wherein the usage information comprises basic information about the usage device and a predicted usage time of the usage device.

5. The method of claim 2, wherein calculating the predicted power amount information comprises:
analyzing the predicted power amount information based on the preset load power data and the available power amount information; and
predicting an estimated time at which the minimum charging amount can be reached based on a result of the analyzing.

6. The method of claim 5, wherein predicting the estimated time comprises predicting an estimated SOC for the battery together with the estimated time.

7. The method of claim 6, wherein predicting the estimated time further comprises:
transmitting a remaining time until the minimum charging amount to the user's device based on the estimated time; and
transmitting a notification to the user's device before the estimated time has been reached.

8. The method of claim 7, wherein predicting the estimated time comprises resetting the minimum charging amount before the estimated time is reached.

9. The method of claim 2, wherein setting the minimum charging amount comprises:
measuring and recording power data of a new device while the new device is being operated by the battery; and
transmitting the power data of the new device to a server.

10. A non-transitory computer-readable recording medium storing a program for executing the method according to claim 1.

11. An electric vehicle state of charge (SOC) control system, the system comprising:
a non-transitory computer-readable recording medium configured to store at least one computer program; and
a processor configured to execute the at least one computer program to perform an SOC control method, wherein, when executing the at least one computer program, the processor is configured to:
set available power amount information based on power of a battery;
receive usage information on a usage device selected by a user from an external device and matching the usage information to preset load power data of a preset load power database;
calculate predicted power amount information of the usage device based on the preset load power data and the available power amount information; and
provide the predicted power amount to a user's device.

12. The system of claim 11, wherein, to set the available power amount information, the processor is configured to:
extract a characteristic value of power consumption according to a type of the electric vehicle;
sense a current external temperature of the electric vehicle;
extract a temperature weight value by matching the sensed current external temperature to a preset temperature factor;
calculate a current SOC of the battery by applying the characteristic value of power consumption or the temperature weight value to the power of the battery; and
calculate an available power amount value based on a minimum charging amount of the battery and the calculated current SOC of the battery.

13. The system of claim 12, wherein the available power amount information comprises the current SOC of the battery, the available power amount value, the characteristic value of power consumption, or the temperature weight value.

14. The system of claim 12, wherein the usage information comprises basic information about the usage device and a predicted usage time of the usage device.

15. The system of claim 12, wherein, to calculate the predicted power amount information, the processor is configured to:
analyze the predicted power amount information based on the preset load power data and the available power amount information; and
predict an estimated time at which the minimum charging amount can be reached based on a result of the analyzing.

16. The system of claim 15, wherein, to predict the estimated time, the processor is configured to predict an estimated SOC for the battery together with the estimated time.

17. The system of claim 16, wherein, to predict the estimated time, the processor is further configured to:
transmit a remaining time until the minimum charging amount to the user's device based on the estimated time; and
transmit a notification to the user's device before the estimated time has been reached.

18. The system of claim 17, wherein, to predict the estimated time, the processor is configured to reset the minimum charging amount before the estimated time is reached.

19. The system of claim 12, wherein, to set the minimum charging amount, the processor is configured to:
measure and record power data of a new device while the new device is being operated by the battery; and
transmit the power data of the new device to a server.

20. An electric vehicle comprising:
a vehicle body;
a battery coupled to the vehicle body;
a controller housed in the electric vehicle;
a server configured to communicate with the controller of the electric vehicle, wherein the server comprises:
a non-transitory computer-readable recording medium configured to store at least one computer program; and
a processor configured to execute the at least one computer program to perform steps of a state of charge (SOC) control method, the steps comprising:
setting available power amount information based on power of the battery;
receiving usage information on a usage device selected by a user from an external device and matching the usage information to preset load power data of a preset load power database;
calculating predicted power amount information of the usage device based on the preset load power data and the available power amount information; and
providing the predicted power amount to a user's device.
